(19) United States
(12) Patent Application Publication
(10) Pub. No.: US 2007/0029895 A1
(43) Pub. Date: Feb. 8, 2007

(54) Structure capable of automatically locating and supporting nodal point of a piezoelectric stator

(75) Inventors: Byung Woo Kang, Seoul (KR); Dong Kyun Lee, Seoul (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 11/498,019

(22) Filed: Aug. 3, 2006

(30) Foreign Application Priority Data
Aug. 5, 2005 (KR) 10-2005-71759

(51) Int. Cl. H01L 41/00

(52) U.S. Cl. 310/311

(57) ABSTRACT

A structure capable of automatically supporting a nodal point of a piezoelectric stator is provided. The structure includes a piezoelectric stator constructed of at least one piezoelectric element and having at least one nodal point; at least one elastic member elastically contacting the piezoelectric stator via the piezoelectric element; a holder arranged around the piezoelectric stator and mounted with the elastic member; and a power supply for applying an electric field to the piezoelectric element via the elastic member. The elastic member automatically locates and contacts the nodal point of the piezoelectric stator owing to the strain of the piezoelectric stator when the electric field is applied to the piezoelectric element. As the nodal point of the piezoelectric stator is correctly supported, oscillation efficiency of the piezoelectric stator is maximized.

### CLAIM OF PRIORITY

This application claims the benefit of Korean Patent Application No. 2005-0071759 filed on Aug. 5, 2005, in the Korean Intellectual Property Office, the disclosure of which is incorporated herein by reference.

### BACKGROUND OF THE INVENTION

1. Field of the Invention

The present invention relates to a piezoelectric ultrasonic motor, and more particularly, to a structure capable of automatically supporting a nodal point of a piezoelectric stator which is equipped in a piezoelectric ultrasonic motor.

2. Description of the Related Art

A piezoelectric element is made of a material that generates a strain in response to an electric field applied thereto but a voltage in response to a stress applied thereto. An oscillator constructed of such a piezoelectric element (hereinafter will be referred to as “piezoelectric stator”) operates at a natural (resonant) frequency in the range from tens to hundreds kHz, and transfers strain amplified through a stacked or strain-enhancing structure to a rotary shaft.

The piezoelectric element is used as an oscillator by itself or in combination with a structure of a specific geometry. The piezoelectric element generates a necessary level of strain in response to a specific frequency, input waveform and phase difference of a natural frequency ranging from tens to hundreds kHz. The strain of the piezoelectric element generating at such a natural frequency is expressed by natural modes such as first, second and third modes, and a structure of such a piezoelectric element in each mode has a nodal point where strain is zero (0) theoretically (see FIG. 2B).

The oscillation efficiency of the piezoelectric stator can be enhanced when an electric field is applied to the piezoelectric stator through a nodal point or an adjacent point.

Conventionally, as shown in FIG. 1, a wire 20 or a Flexible Printed Circuit Board (FPCB) is attached to an electrode surface adjacent to a nodal point of a piezoelectric element 10 using a solder 30 or a conductive paste such as silver (Ag) paste.

However, such a process including the soldering has some drawbacks in that the electrode surface of the piezoelectric element 10 may be damaged, the solder may be separated owing to repeated oscillation, and the electrode may be delaminated under harsh conditions.

The process also has problems such as torn wire owing to cumulative fatigue, electrode surface deteriorated under soldering heat, and degraded admittance characteristics owing to nonuniform solder amount.

Furthermore, in a case where the solder is not applied correctly to the nodal point, an admittance value indicating oscillation magnitude is relatively reduced thereby lowering oscillation efficiency.

### SUMMARY OF THE INVENTION

The present invention has been made to solve the foregoing problems of the prior art and therefore an object of certain embodiments of the present invention is to provide a structure capable of automatically locating and supporting a power supply on a nodal point of a piezoelectric stator when an electric field is applied to a piezoelectric element.

Another object of certain embodiments of the invention is to provide a structure capable of automatically locating and supporting a nodal point of a piezoelectric stator so that a supply voltage is applied precisely to a nodal point to maximize oscillation efficiency.

Further another object of certain embodiments of the invention is to provide a structure capable of automatically locating and supporting a nodal point of a piezoelectric stator in order to prevent wire disconnection, electrode surface degradation owing to soldering or soldering heat, oscillation efficiency degradation owing to nonuniform solder amount, electrode delamination and so on.

According to an aspect of the invention for realizing any of the objects, there is provided a structure capable of automatically locating and supporting a nodal point of a piezoelectric stator. The structure includes: a piezoelectric stator constructed of at least one piezoelectric element and having at least one nodal point; at least one elastic member elastically contacting the piezoelectric stator via the piezoelectric element; a holder arranged around the piezoelectric stator and mounted with the elastic member; and a power supply for applying an electric field to the piezoelectric element via the elastic member, whereby the elastic member automatically locates and contacts the nodal point of the piezoelectric stator owing to the strain of the piezoelectric stator when the electric field is applied to the piezoelectric element.

Preferably, the elastic member comprises a coil spring.

Here, the elastic member includes a contact member contacting the piezoelectric element, a coil spring providing an elastic force for elastic contact of the contact member with the piezoelectric element and a housing for holding the coil spring and the contact member without separation.

Preferably, the contact member has an arc-shaped cross section.

Preferably, the elastic member includes a leaf spring elastically contacting the piezoelectric element.

Preferably, the piezoelectric stator includes a body and a plurality of the piezoelectric element attached to the exterior of the body, in which the elastic member may be provided by plurality so that each of the elastic members elastically contacts each of the piezoelectric elements.

Alternatively, the piezoelectric stator includes a body and a plurality of the piezoelectric element attached to the exterior of the body, in which each of the piezoelectric elements contacts the at least one elastic member and at least one support member of the holder.

Preferably, the piezoelectric stator has a configuration selected from the group consisting of a cylinder, a prism or a hollow tube, and wherein the holder receives the piezoelectric stator therein to be movable in a longitudinal direction.

Furthermore, the power supply is preferably mounted on the exterior of the holder and electrically connected to the elastic member.

Here, the power supply comprises an FPCB.

According to another aspect of the invention for realizing any of the objects, there is provided a structure capable of automatically locating and supporting a nodal point of a piezoelectric stator. The structure includes: a piezoelectric stator having at least one nodal point, the piezoelectric stator including a body and a plurality of piezoelectric elements arranged on the exterior of the body at a predetermined angle; at least one elastic member elastically contacting the piezoelectric stator via the piezoelectric element; a holder receiving the piezoelectric stator therein to be movable in a longitudinal direction and mounted with the elastic member; a power supply for applying an electric field to the piezoelectric element via the elastic member; and a rotary shaft contacting the piezoelectric stator to rotate in response to the oscillation of the piezoelectric stator, whereby the elastic member automatically locates and contacts the nodal point of the piezoelectric stator owing to the strain of the piezoelectric stator when the electric field is applied to the piezoelectric element.

Preferably, the structure may further comprise a preload member for maintaining the piezoelectric stator and the rotary shaft in a preloaded position.

Preferably, the elastic member includes a contact member contacting the piezoelectric element, a coil spring providing an elastic force for elastic contact of the contact member with the piezoelectric element and a housing for holding the coil spring and the contact member without separation.

Here, the contact member has an arc-shaped cross section.

Preferably, the elastic member includes a leaf spring elastically contacting the piezoelectric element.

Preferably, the structure may comprise a plurality of the elastic member each of which elastically contacts each of the piezoelectric elements.

Preferably, each of the piezoelectric elements contacts the at least one elastic member and at least one support member of the holder.

Furthermore, the piezoelectric stator has a configuration selected from the group consisting of a circular cylinder, a prism or a hollow tube.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a schematic view illustrating a structure for applying a voltage to a piezoelectric stator according to the prior art;

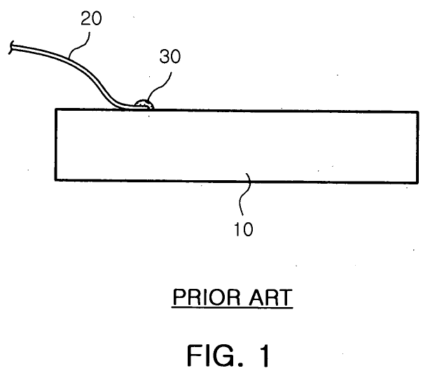

FIG. 2A is a perspective view illustrating a general tubular piezoelectric stator;

FIG. 2B is a perspective view illustrating a strain distribution together with nodal points on a conventional tubular piezoelectric stator;

FIG. 3 is a schematic view illustrating a concept of a structure for automatically locating and supporting a nodal point of a piezoelectric stator according to the invention;

FIG. 4 is a schematic view illustrating exemplary structures for automatically locating and supporting a nodal point of a piezoelectric stator according to embodiments of the invention;

FIG. 5 is an exploded perspective view illustrating a structure for automatically locating and supporting a nodal point of a piezoelectric stator according to the invention;

FIG. 6 is an assembled perspective view illustrating a structure for automatically locating and supporting a nodal point of a piezoelectric stator according to the invention;

FIG. 7 is a cross sectional view illustrating elastic members according to embodiments of the invention;

FIG. 8 is a perspective view illustrating a holder of the invention;

FIG. 9 is an exploded perspective view illustrating a ultrasonic piezoelectric motor of the invention; and

FIG. 10 is an exploded perspective view illustrating a structure for automatically locating and supporting a nodal point of a piezoelectric stator according to another embodiment of the invention.

### DETAILED DESCRIPTION OF THE PREFERRED EMBODIMENT

The present invention will now be described more fully hereinafter with reference to the accompanying drawings, in which preferred embodiments of the invention are shown.

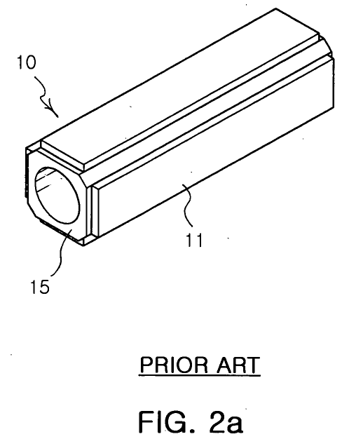

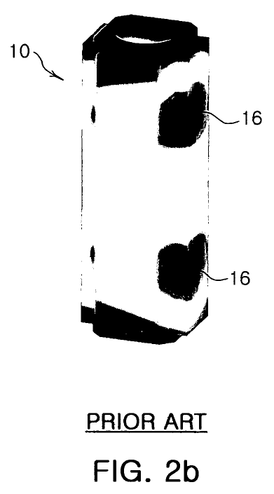

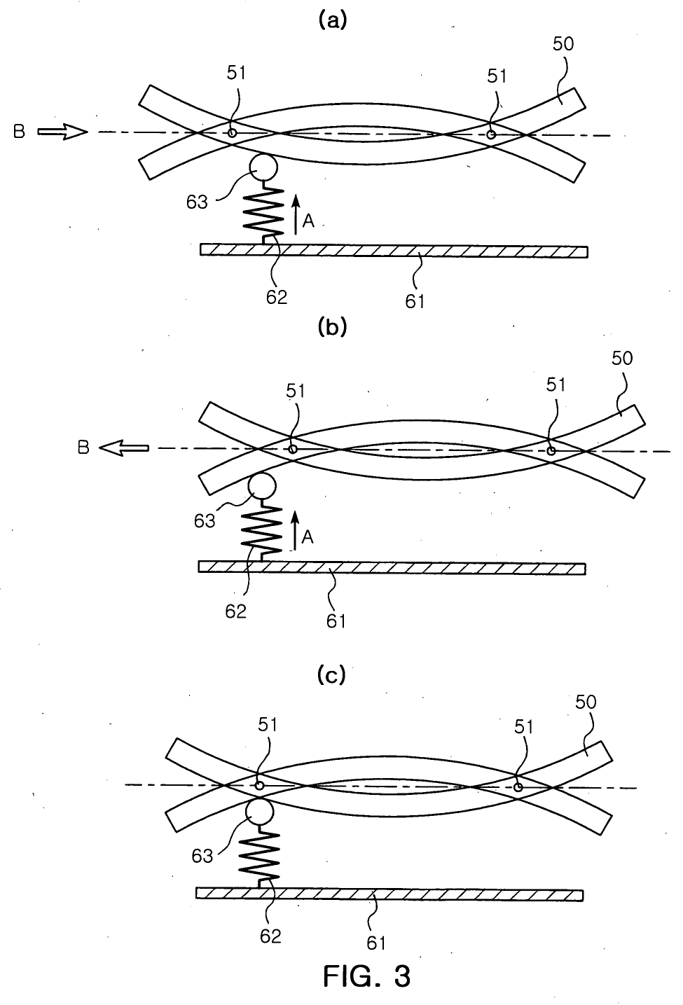

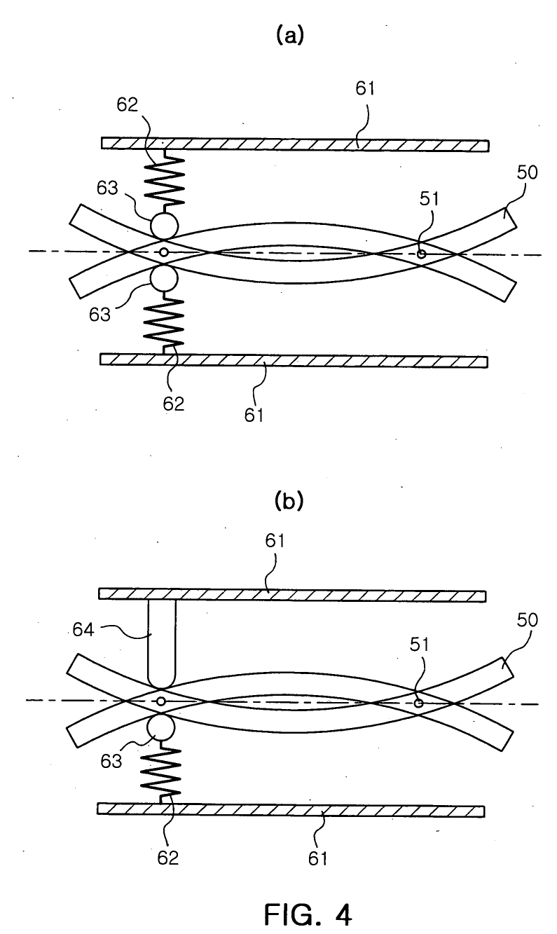

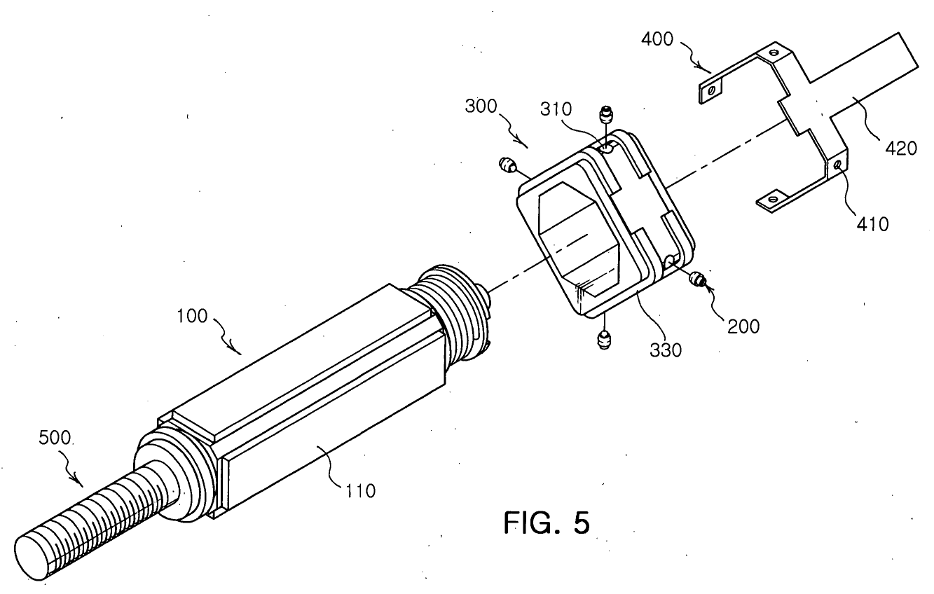

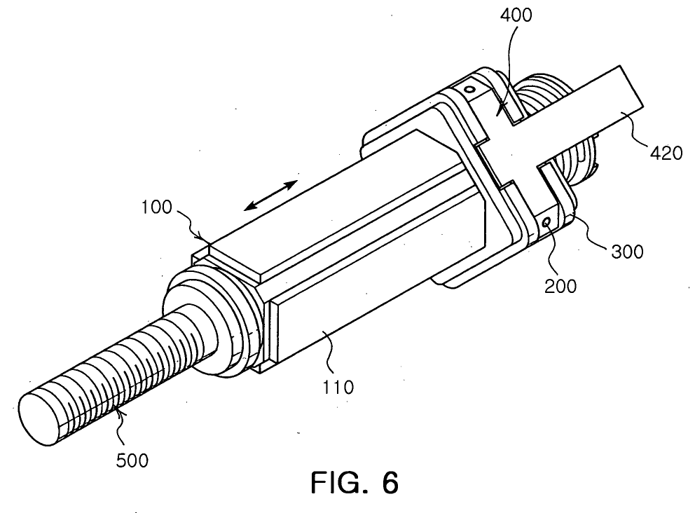

FIG. 2A is a perspective view illustrating a general tubular piezoelectric stator, FIG. 2B is a perspective view illustrating a strain distribution together with nodal points on a conventional tubular piezoelectric stator, FIG. 3 is a schematic view illustrating a concept of a structure for automatically locating and supporting a nodal point of a piezoelectric stator according to the invention, FIG. 4 is a schematic view illustrating exemplary structures for automatically locating and supporting a nodal point of a piezoelectric stator according to embodiments of the invention, FIG. 5 is an exploded perspective view illustrating a structure for automatically locating and supporting a nodal point of a piezoelectric stator according to the invention, FIG. 6 is an assembled perspective view illustrating a structure for automatically locating and supporting a nodal point of a piezoelectric stator according to the invention.

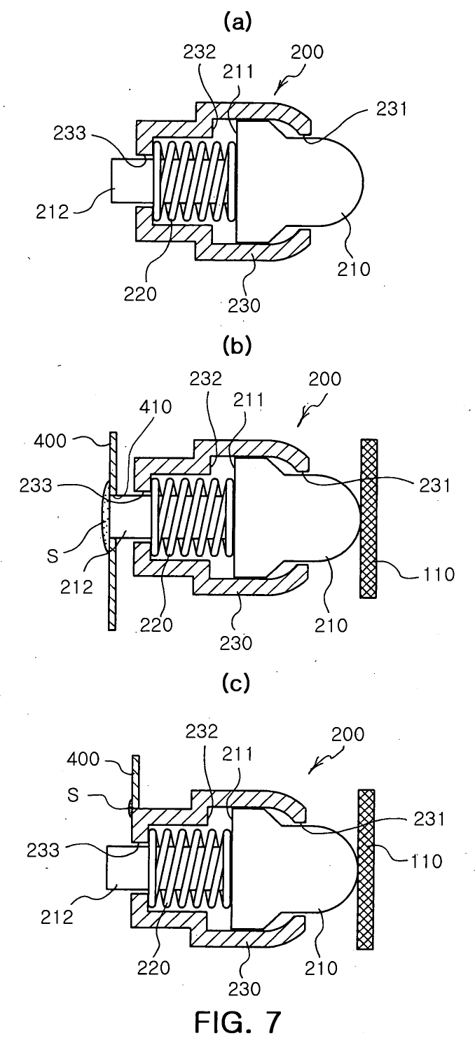

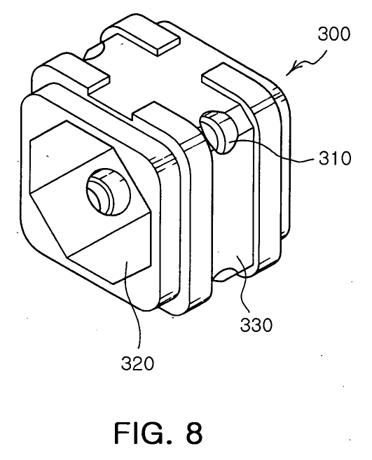

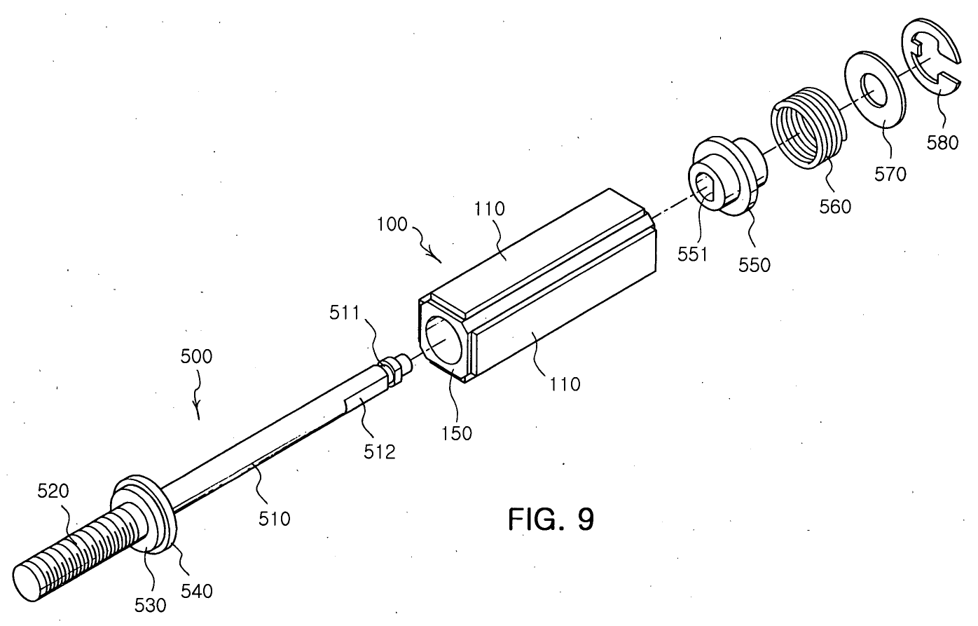

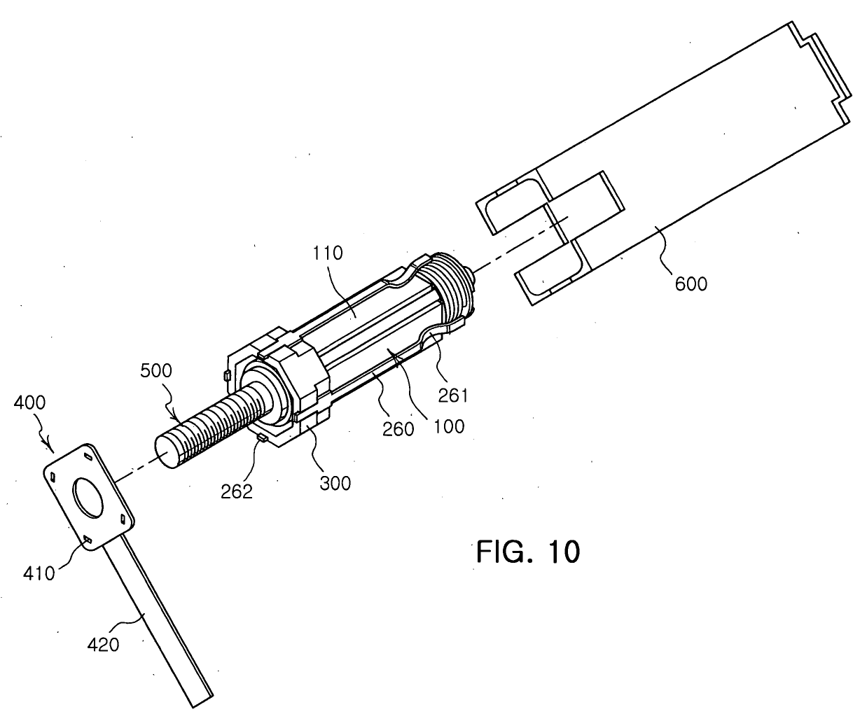

Furthermore, FIG. 7 is a cross sectional view illustrating elastic members according to embodiments of the invention, FIG. 8 is a perspective view illustrating a holder of the invention, FIG. 9 is an exploded perspective view illustrating a ultrasonic piezoelectric motor of the invention, and FIG. 10 is an exploded perspective view illustrating a structure for automatically locating and supporting a nodal point of a piezoelectric stator according to another embodiment of the invention.

In general, a piezoelectric stator constructed of a piezoelectric element has at least one nodal point where strain is zero (0) theoretically.

For example, as shown in FIG. 2A, a piezoelectric stator 10 with a plurality of piezoelectric elements 11 equipped on the exterior of a hollow body 15 has two nodal points as shown in FIG. 2B.

Such nodal points of the piezoelectric stator 10 can be varied according to the polarization direction and shape of the piezoelectric elements 11 and phase difference applied to the piezoelectric elements 11.

To maximize the oscillation efficiency of the piezoelectric stator 10, it is necessary to apply an electric field to the nodal points 16 precisely.

In order to supply the electric field to the nodal points precisely, the present invention aims to automatically and precisely support the nodal points and precisely apply the electric field to the nodal point by using the strain of the piezoelectric stator and the elasticity of elastic members.

First, the concept of the invention for automatically locating and supporting the nodal points of a piezoelectric stator will be described with reference to FIG. 3.

As shown in (a) of FIG. 3, a contact member 63 is connected to an elastic member 62 fixed to a stationary part 61 so that it contacts a piezoelectric stator 50. The piezoelectric stator 50 oscillates when applied with an electric field.

When the piezoelectric stator 50 oscillates with the electric field applied thereto, the piezoelectric stator 50 moves in the direction of arrow B to a position shown in (c) of FIG. 3 under the elastic force of the elastic member 62 so that the contact member 63 contacts a nodal point 51 where the elastic force A is minimal. That is, the piezoelectric stator 50 moves to the position where the elastic force of the elastic member 62 becomes minimum.

Also in case of (b) of FIG. 3, the piezoelectric stator 50 moves in the direction of arrow B to the position shown in (c) of FIG. 3 so that the contact member 63 contacts the nodal point 51 where the elastic force A is minimal.

By using the elastic force and strain, the contact member 63 can contact the nodal point 51 precisely, where oscillation efficiency can be maximized when applied with a voltage.

In a case where the piezoelectric stator 50 is fixed and the elastic members 62 and the contact member 63 are movable, the contact member 63 may move to support the piezoelectric stator 50 at the nodal point 51 precisely.

FIG. 4 illustrates exemplary structures for supporting the piezoelectric stator 50.

As shown in (a) of FIG. 4, two (or more) contact members 63 may be provided to contact a piezoelectric stator 50 at two (or more) points. Preferably, the contact members 63 may be spaced from each other at a predetermined interval at the exterior of the piezoelectric stator 50 in order to impart a uniform elastic force to the piezoelectric stator 50.

Alternatively, as shown in (b) of FIG. 4, one (or more) support member 64 and one (or more) contact member 63 may be provided to contact a piezoelectric stator 50.

As shown in FIG. 5, a structure capable of automatically locating and supporting a nodal point of a piezoelectric stator according to the invention includes a piezoelectric stator 100, elastic members 200, a holder 300 and a power supply 400.

The piezoelectric stator 100 includes four piezoelectric elements 110 (or at least one stator), and has nodal points at predetermined positions when the piezoelectric elements 110 oscillate.

Here, the piezoelectric stator 100 may have but not limited to a tubular configuration as shown in FIG. 9, which includes a hollow body 150 and the piezoelectric elements 110 attached to the exterior of the body 150.

That is, the piezoelectric stator 100 may adopt any types of piezoelectric stators having at least one nodal point. For example, the piezoelectric stator 100 may be shaped as a hollow cylinder, a hollow prism or a hollow tube having a circular cross section.

Furthermore, the piezoelectric stator 100 of the invention is not limited to the configuration as shown in FIG. 9 where the piezoelectric elements 110 are attached to the exterior of the body 15. That is, the piezoelectric stator 100 of the invention may be embodied by a single piezoelectric element, a plurality of piezoelectric elements connected together without a body, or a plurality of piezoelectric elements stacked on each other.

Of course, the polarization direction of the piezoelectric element 110 is not limited either.

The piezoelectric element 110 may be mounted on the exterior of the body 150 by plurality. Particularly, four of the piezoelectric element 110 may be mounted on the exterior of the body 150 at a predetermined interval from each other.

As shown in FIG. 5, the elastic members 200 are mounted on seating openings 310 of the holder 300, and elastically contact the piezoelectric elements 110 of the piezoelectric stator 100, respectively.

As stated above, when an electric field is applied to the piezoelectric elements 110, the strain of the piezoelectric stator 100 makes the elastic members 200 contact the corresponding nodal points of the piezoelectric stator 100. For this purpose, the elastic members 200 provide elastic force necessary for the movement of the holder 300 or the piezoelectric stator 100.

Here, each of the elastic members 200 corresponds to each of the piezoelectric elements 110 so as to contact the electrode surface of the each piezoelectric element 110, and serves to transfer an electric field applied through the power supply 400 to the piezoelectric element 110. For this purpose, the elastic members 200 are made of a conductive material such as metal.

Now the elastic members 200 will be described in more detail with reference to FIG. 7.

As shown in FIG. 7, the elastic member 200 may include a coil spring 220.

In this case, the elastic member 200 includes a contact member 210 and a housing 230 together with the coil spring 220. The contact member 210 contacts the piezoelectric element 110, and the coil spring 220 provides an elastic force allowing the contact member 210 to elastically contact the piezoelectric element 110. The housing 230 houses the coil spring 220 and the contact member 210, preventing them from separating from each other.

The contact member 210 preferably has an arc-shaped cross section not to damage the electrode surface of the piezoelectric element 110. This shape also affords a low friction against the piezoelectric element 110 as shown in FIG. 6 so that the piezoelectric stator 100 can move freely. That is, the contact member 210 preferably performs point contact with the piezoelectric element 210.

The elastic members 200 each with the contact member 210 are provided on the exterior of the piezoelectric stator 100, and preferably spaced from each other at a predetermined interval to provide a uniform elastic force to the piezoelectric stator 100.

In a case where a plurality of such piezoelectric elements 110 are attached to the exterior of the body 150, each piezoelectric element 110 may be configured to contact one or more elastic members 200 and one or more support member (64 in FIG. 4B) which is protruded from the holder 300 to contact the piezoelectric element 110. Even in this case, a set of the elastic member 200 and the support member may be installed preferably on the exterior of the piezoelectric stator 100, separated from another set at a predetermined interval, to provide a uniform elastic force to the piezoelectric stator 100.

As shown in FIG. 7, the housing 230 has a first opening 231 formed at one end and a second opening 233 formed at the other end. The first opening 231 is opened to expose the contact member 210, and the second opening 233 allows a connecting part 212 of the contact member 210 to be inserted into a hole 410 of the power supply 400.

Furthermore, the housing 230 has a step 232 for contacting a flange 211 of the contact member 210 to restrict the movement of the contact member 210.

As shown in (b) and (c) of FIG. 7, the elastic member 200 contacts the electrode surface of the piezoelectric element 110 via the contact member 210 to conduct an electric field to the piezoelectric element 110. For this purpose, the elastic member 200 is made of a conductive material such as metal.

In this case, while the connecting part 212 is preferably inserted into and soldered in the hole 410 of the power supply 400 as shown in (b) of FIG. 7, the power supply 400 may be configured to apply an electric field to the piezoelectric element 110 via the housing 230 as shown in (c) of FIG. 7.

As shown in FIGS. 5, 6 and 9, the holder 300 is arranged around the piezoelectric stator 100 to accept the elastic members 200 via the sealing openings 310.

As shown in FIG. 8, the holder 300 has a groove 330 for seating the power supply 400 and an opening 320 having a configuration conforming to that of the piezoelectric stator 100. That is, the holder 300 receives the piezoelectric stator 100 therein through the opening 320 in such a fashion that the piezoelectric stator 100 can move in a longitudinal direction.

As shown in FIGS. 5 and 7, the power supply 400 applies an electric field to the piezoelectric element 110 through the elastic member 200.

Here, while the power supply 400 may be made of a wire and the like, it may be constructed of a Flexible Printed Circuit Board (FPCB) which has a hole 410 and an external power connecting part 420 for connection with the elastic member 200 as shown in FIG. 5.

The other end or connecting part 212 of the contact member 210 is inserted through the hole 410, and an electric field can be applied to the piezoelectric stator 100 through a solder S between the connecting part 212 and the hole 410.

In the meantime, as shown in FIG. 10, the elastic member 200 may include leaf springs 260 each of which elastically contacts each of the piezoelectric elements 110.

In case of FIG. 10, the leaf spring 260 contacts and gives elastic force to the piezoelectric stator 100 through a contacting part 261. In addition, the leaf spring 260 is connected through a connecting part 262 with the hole 410 of the power supply 400, such that a voltage is applied to the piezoelectric element 110 through the connection of the connecting part 262 with the hole 410. Also in this case, the leaf spring 260 is made of a conductive material such as metal for the application of the electric field.

In the meantime, as shown in FIGS. 5, 6 and 9, the structure capable of automatically locating and supporting a nodal point of a piezoelectric stator may include a rotary shaft 500 which contacts the piezoelectric stator 100 and rotates in response to the oscillation of the piezoelectric stator 100.

As an example, the rotary shaft 500 includes a rotatable shaft 510 inserted into an inner space of the piezoelectric stator 100, an upper rotatable member 530 contacting an upper part of the body 150 of the piezoelectric stator 100 to rotate in response to the strain of the piezoelectric stator 100, a lower rotatable member 550 contacting a lower part of the body 150 of the piezoelectric stator 100 to rotate in response to the strain of the piezoelectric stator 100, a power transmission member 520 such as a lead screw for transmitting a rotational force from the rotatable member 530 to the outside, a preload member 560 such as a coil spring for pressing the lower rotatable member 550 to enhance contact forces between the upper rotatable member 530 and the piezoelectric stator 100 and between the lower rotatable member 550 and the piezoelectric stator 100, a separation preventing member 580 such as an E-ring fitted into a groove 511 of the rotatable shaft 510 to prevent separation of the preload member 560 and a washer 570 for preventing interference noise.

The lower rotatable member 550 has a recess 551 with a planar part for receiving a cutaway part 512 of the rotatable shaft 510 so that the lower rotatable member 550 can rotate together with the rotatable shaft 510.

The rotary shaft 500 may also include a friction member 540 fixed to the upper rotatable member 530. The friction member 540 is made of a high friction coefficient to enhance a contact force between the upper rotatable member 530 and the upper part of the body 150 of the piezoelectric stator 100.

With the rotary shaft 500 provided as above, the piezoelectric stator 110 is preloaded, and when an electric field is applied, can more easily move so that the elastic member 200 contacts the nodal point of the piezoelectric stator 110.

In the meantime, all of the piezoelectric stator 100, the rotary shaft 500, the elastic member 200 and the holder 300 can be mounted inside the housing 600 to form one module.

The operation of the invention having the above mentioned construction will be described with reference to FIGS. 5 and 6.

The electric field applied from the power supply 400 is transferred to the piezoelectric stator 100 through the elastic members 200 received in the holder 300. In response to the electric field applied thereto, the piezoelectric stator 100 is strained to oscillate.

Such strain causes the elastic force of the elastic members 200 to act on the piezoelectric stator 100 so that the piezoelectric stator 100 moves to contact the elastic members 200 at nodal points where the elastic force is minimum. As the piezoelectric stator 100 is transported to contact the elastic members 200 at the nodal points as set forth above, it is possible to support the nodal points precisely without having to perform a simulation.

Furthermore, since the electric field is applied at the nodal point, oscillation efficiency is maximized.

According to certain embodiments of the invention as described hereinbefore, it is possible to apply a supply voltage precisely to nodal points of the piezoelectric stator thereby maximizing oscillation efficiency.

Furthermore, there is an effect in that the supply voltage can be applied precisely to the nodal points without a precise control.

Moreover, since the voltage is supplied through the elastic members connected to the power supply, an additional process such as soldering is unnecessary. As a result, it is possible to prevent wire disconnection, electrode surface degradation owing to soldering or soldering heat, oscillation efficiency degradation owing to nonuniform solder amount, electrode delamination and so on.

Although the preferred embodiments of the present invention have been disclosed for illustrative purposes, those skilled in the art will appreciate that various modifications, additions and substitutions can be made without departing from the scope and spirit of the invention as disclosed in the accompanying claims.

What is claimed is:

1. A structure capable of automatically locating and supporting a nodal point of a piezoelectric stator comprising:
a piezoelectric stator constructed of at least one piezoelectric element and having at least one nodal point;
at least one elastic member elastically contacting the piezoelectric stator via the piezoelectric element;
a holder arranged around the piezoelectric stator and mounted with the elastic member; and
a power supply for applying an electric field to the piezoelectric element via the elastic member,
whereby the elastic member automatically locates and contacts the nodal point of the piezoelectric stator owing to the strain of the piezoelectric stator when the electric field is applied to the piezoelectric element.

2. The structure of claim 1, wherein the elastic member includes a contact member contacting the piezoelectric element, a coil spring providing an elastic force for elastic contact of the contact member with the piezoelectric element and a housing for holding the coil spring and the contact member without separation.

3. The structure of claim 2, wherein the contact member has an arc-shaped cross section.

4. The structure of claim 1, wherein the elastic member includes a leaf spring elastically contacting the piezoelectric element.

5. The structure of claim 1, wherein the piezoelectric stator includes a body and a plurality of the piezoelectric element attached to the exterior of the body, and
wherein each of the piezoelectric elements contacts the at least one elastic member and at least one support member of the holder.

6. The structure of claim 1, wherein the piezoelectric stator has a configuration selected from the group consisting of a cylinder, a prism or a hollow tube, and
wherein the holder receives the piezoelectric stator therein to be movable in a longitudinal direction.

7. The structure of claim 1, wherein the power supply is mounted on the exterior of the holder and electrically connected to the elastic member.

8. A structure capable of automatically locating and supporting a nodal point of a piezoelectric stator comprising:
a piezoelectric stator having at least one nodal point, the piezoelectric stator including a body and a plurality of piezoelectric elements arranged on the exterior of the body at a predetermined angle;
at least one elastic member elastically contacting the piezoelectric stator via the piezoelectric element;
a holder receiving the piezoelectric stator therein to be movable in a longitudinal direction and mounted with the elastic member;
a power supply for applying an electric field to the piezoelectric element via the elastic member; and
a rotary shaft contacting the piezoelectric stator to rotate in response to the oscillation of the piezoelectric stator,
whereby the elastic member automatically locates and contacts the nodal point of the piezoelectric stator owing to the strain of the piezoelectric stator when the electric field is applied to the piezoelectric element.

9. The structure of claim 8, further comprising a preload member for maintaining the piezoelectric stator and the rotary shaft in a preloaded position.

10. The structure of claim 8, wherein the elastic member includes a contact member contacting the piezoelectric element, a coil spring providing an elastic force for elastic contact of the contact member with the piezoelectric element and a housing for holding the coil spring and the contact member without separation.

11. The structure of claim 10, wherein the contact member has an arc-shaped cross section.

12. The structure of claim 8, wherein the elastic member includes a leaf spring elastically contacting the piezoelectric element.

13. The structure of claim 8, further comprising a plurality of the elastic member each of which elastically contacts each of the piezoelectric elements.

14. The structure of claim 8, wherein each of the piezoelectric elements contacts the at least one elastic member and at least one support member of the holder.

15. The structure of claim 8, wherein the piezoelectric stator has a configuration selected from the group consisting of a circular cylinder, a prism or a hollow tube.
